(19) United States
(12) Patent Application Publication
(10) Pub. No.: US 2015/0046763 A1
(43) Pub. Date: Feb. 12, 2015

(54) Apparatus and Method for Controlling Internal Test Controllers

(71) Applicant: Apple Inc., Cupertino, CA (US)

(72) Inventors: Samy R. Makar, Fremont, CA (US); Jianlin Yu, Cupertino, CA (US); Ravi K. Ramaswami, Cupertino, CA (US)

(73) Assignee: Apple Inc., Cupertino, CA (US)

(21) Appl. No.: 13/964,463

(22) Filed: Aug. 12, 2013

(51) Int. Cl. G01R 31/3177

(52) U.S. Cl. CPC G01R 31/3177
USPC 714/727

(57) ABSTRACT

An apparatus and method for controlling a test controller is disclosed. An apparatus includes test controllers of a first type configured to operate according to a first protocol and test controllers of a second type configured to operate according to a second protocol. A test controller of the second type may be associated with one of the test controllers of the first type, with the former controlling the latter. The test controllers of the second type may each control associated ones of the test controllers of the second type in parallel and independently of one another.

### BACKGROUND

1. Technical Field

This disclosure is directed to integrated circuits, and more particularly, to the access of test interfaces for integrated circuits.

2. Description of the Related Art

Boundary scan testing was originally developed to test connections between integrated circuits (IC's) and printed circuit boards (PCB's) in the absence of other ways to probe them. Boundary scan is based on the Joint Test Action Group (JTAG) specification, which is also known at the Institute of Electrical and Electronic Engineers (IEEE) Standard 1149.1. In particular, the IEEE 1149.1 standard provided a mechanism for providing access to pins of an IC to determine the presence of proper connections.

Although the IEEE 1149.1 standard was originally developed for boundary scan, its uses have expanded to other areas. For example, JTAG ports are now used to obtain access to an IC for debugging during the development phase. For example, a JTAG controller may be used to access portions of an IC while conducting tests of system software in a new design.

In light of the above, multiple JTAG controllers may be implemented in an IC, with some of them being internal to the IC and thus not directly accessible from external pins. In such cases, the JTAG controllers may be coupled together in a series configuration (“daisy-chained”) to allow access to those that are internal to the IC. Any number of JTAG controllers may be coupled to one another in series, and thus they may be used in large, complex IC designs.

### SUMMARY

An apparatus and method for controlling a test controller is disclosed. An apparatus includes test controllers of a first type configured to operate according to a first protocol and test controllers of a second type configured to operate according to a second protocol. A test controller of the second type may be associated with one of the test controllers of the first type, with the former controlling the latter. The test controllers of the second type may each control associated ones of the test controllers of the second type in parallel and independently of one another.

In one embodiment, the controllers of the first type are Joint Test Action Group (JTAG) controllers, conforming to the IEEE 1149.1 Standard. The controllers of the second type are Embedded Core Test (ECT) controllers, conforming to the IEEE 1500 Standard. Thus, a given ECT controller may control its respectively coupled JTAG controller, independently and in parallel with other ECT controllers controlling their respectively coupled JTAG controllers.

A partition selection register may be implemented to invoke the control of a given JTAG controller by a respectively coupled ECT controller. In one embodiment, the partition selection register includes a number of storage locations. Each of the ECT controllers is associated with a corresponding storage location in the ECT. When a bit is set in a storage location associated with a particular ECT, the ECT may be activated to control its corresponding JTAG controller. Controlling the JTAG controller may include the ECT providing a test mode select (TMS) signal to the JTAG controller, inputting data/instructions into the JTAG controller through its test data input (TDI), and gating a test clock signal (TCK) provided to the JTAG controller. The ECT may also receive data from its respective JTAG controller via a test data output (TDO) of the latter.

### BRIEF DESCRIPTION OF THE DRAWINGS

The following detailed description makes reference to the accompanying drawings, which are now briefly described.

FIG. 1 is a block diagram of one embodiment of an integrated circuit (IC).

FIG. 2 is a block diagram illustrating the control of a first controller by a second controller.

FIG. 3 is a flow diagram illustrating one embodiment of a method for controlling a JTAG controller using an ECT controller.

FIG. 4 is a block diagram of one embodiment of an exemplary system.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include”, “including”, and “includes” mean including, but not limited to.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. §112, paragraph six interpretation for that unit/circuit/component.

### DETAILED DESCRIPTION OF EMBODIMENTS

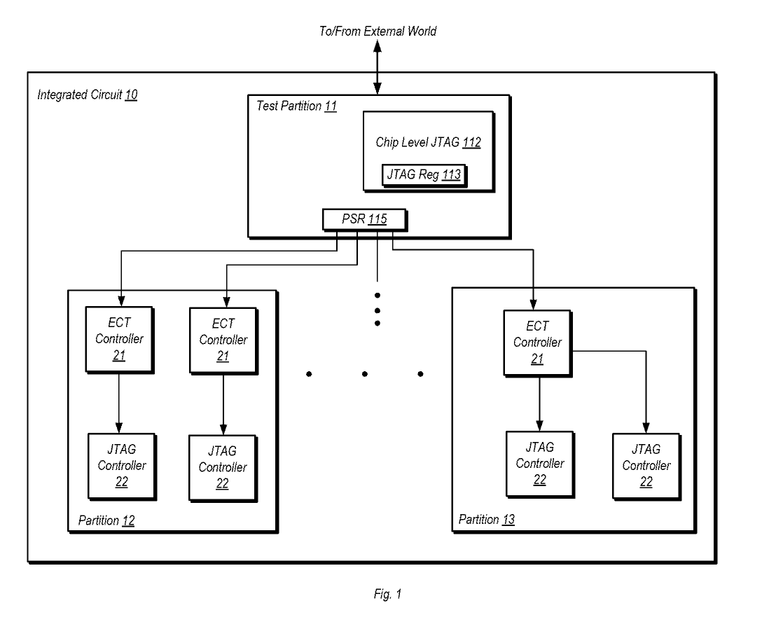

Turning now to FIG. 1, a block diagram of one embodiment of an integrated circuit (IC) is shown. It is noted that FIG. 1 is a simplified block diagram that does not show many elements of a typical IC, such as the functional units that perform the various operations therein. The block diagram shown here is simplified to more clearly illustrate the particular functionality disclosed herein and discussed in further detail below.

In the embodiment shown, IC 10 includes a number of different partitions, including partition 11, partition 12, and partition 13. A partition may be defined herein in various ways. For example, a partition may be defined as a group of related circuits, such as those circuits of a particular functional units or circuits that are generally related by function. A partition may also be defined by the circuits that are included in a particular power domain and/or clock domain. In general, a partition may be defined by circuits that are related by at least one aspect other than the fact that they are implemented on the same IC, and wherein the aspect that defines a partition is not applicable to all circuitry implemented on the IC (i.e. there are multiple partitions). To use one specific example, an IC may include a first partition dedicated to input/output (I/O) circuitry, a second partition dedicated to general processing circuitry, and a third partition dedicated to graphics processing circuitry.

Two of the partitions in the embodiment shown, partition 12 and partition 13, include at least one ECT controller 21 (confirming to the IEEE 1500 standard) with a correspondingly coupled JTAG controller 22 (conforming to the IEEE 1149.1 standard, and sometimes referred to as a TAP, or test access port). Partitions 11 and 12 themselves may be partitions as described above that each includes circuitry that shares at least one particular defining aspect. In some embodiments, an ECT controller 21 may be coupled to multiple JTAG controllers 22

Another partition in IC 10 is test partition 11, which is generally dedicated to supporting test and debug functionality. Access to internal portions of IC 10 from a point external thereto may be among the specific functions provided by test partition 11. In this particular embodiment, test partition 11 includes a chip-level JTAG controller 112. JTAG controller 112 includes a JTAG register 113, which may include storage locations for each of a number of internal JTAG controllers 22 implemented on IC 10.

Each storage location of JTAG register 113 that is associated with an internal JTAG controller 22 may include at least one bit, that when set, enables its associated JTAG controller 22 for operation. It is noted that JTAG register 113 may have other storage locations that are not explicitly associated with any one of the JTAG controllers 22 within IC 10.

Test partition 11 also includes a partition select register (PSR) 115. Similar to JTAG register 113, PSR 115 may include a number of storage locations that are associated with corresponding ones of a number of ECT controllers 21. The ECT controllers 21 in the embodiment shown conform to the IEEE 1500 standard. Setting a bit in an associated storage location may cause an ECT controller 21 to control its correspondingly coupled JTAG controller 22. Moreover, the control of two or more individual JTAG controllers 21 (within the same partition or within different partitions) may be performed separately and independently by the correspondingly coupled ECT controllers, and in parallel with others. For example, an ECT controller 21 in partition 12 may control its correspondingly coupled JTAG controller 22 concurrently with and independently of an ECT controller 21 in partition 13 controlling its correspondingly coupled JTAG controller 22.

The ability of the ECT controllers 21 to control their respectively coupled JTAG controllers 22 may simplify their control relative to previous methods. In many prior art embodiments, controlling internal JTAG controllers involved coupling them in a series configuration. Thus, the inputting of instructions and/or test data (and the outputting thereof) could in some cases involve that information being conveyed through several JTAG controllers. This increased the complexity of inputting and outputting information from internal JTAG controllers, while also consuming more time. In contrast, the ability to control JTAG controllers using the ECT controllers as described herein eliminates any need to coupled JTAG controllers in series.

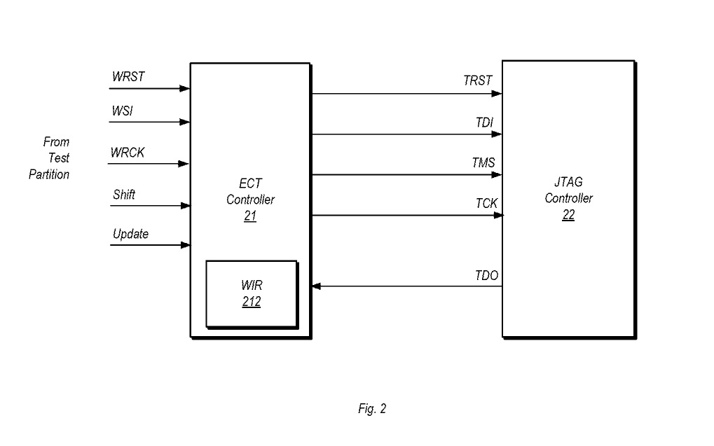

FIG. 2 is a block diagram illustrating the control of a first controller by a second controller. In the embodiment shown, an ECT controller 21 is coupled to JTAG controller 22. Moreover, the typical signals associated with JTAG are received by JTAG controller 22 from ECT controller 21. JTAG controller 22 includes a test reset (TRST) input, a test data input (TDI), a test mode select (TMS) input, and a test clock (TCK) input. Additionally, JTAG controller 22 includes a test data output (TDO) coupled to corresponding inputs of ECT controller 21.

ECT controller 21 in the embodiment shown is configured to receive from test partition 11 the following signals: wrapper reset (WRST), wrapper serial input (WSI; a data input), wrapper clock (WRCK), a shift signal (‘Shift’) and an update signal (‘Update’). These signals may be generated within test partition 11 by other circuitry, or may be input into IC 10 from an external source.

ECT controller 21 in the embodiment shown also includes a wrapper instruction register (WIR) 212. Among other functions, WIR 212 may be used to serially load and store instructions per the IEEE 1500 standard. In addition, WIR 212 may provide an interface to other circuitry internal to ECT controller 21 for controlling such functions as data input into the JTAG controller 22 and gating of the TCK signal.

The WRST signal, when received by ECT controller 21, may assert the TRST signal and thus invoke a reset thereof. In one embodiment, the WRST signal may pass through ECT controller via a simple wire to the TRST input of JTAG controller 22. In other embodiments, the WRST signal may also be provided to logic in ECT controller 21 for performing a reset thereof.

Test data and instructions may be serially input into the ECT controller 21 in the illustrated embodiment, via the WSI. ECT controller 21 may include one or more delays (e.g., flip-flops) through which the test data passes from the WSI to the TDI of JTAG controller 22.

The WRCK signal may be input into ECT controller 21 and may be used to generate the TCK signal. The TCK signal may be gated, and thus provided to JTAG controller 22 only at specific times. In this particular embodiment, activation of the clock requires either an asserted internal TMS signal (from WIR 212) or the setting of an internal WIR TDI signal being set to a logic 1 (also from WIR) along with one of two other conditions: the Shift signal is set to a logic 1, or the update signal is set to logic 1 and the WIR TDI signal also being set to logic 1. When one of these conditions is true, then the TCK signal may cycle as normal. The TCK clock signal is otherwise gated, which may be used to ensure that JTAG controller 21 holds its state at the completion of an operation.

The Shift signal may be used to enable shift operations. As noted above, the Shift signal may be one of the signals used in determining whether the TCK signal is to be gated. The Update signal may also be used in determining whether the TCK signal is to be gated as noted above. Additionally, the Update signal may be used to enable the updating of WIR 212 and other registers (not shown) in ECT controller 21.

Captured test data may be provided by JTAG controller 22 to ECT controller 21 via the TDO of the former. In one embodiment, WIR 212 may receive data shifted from the TDO of JTAG controller 22.

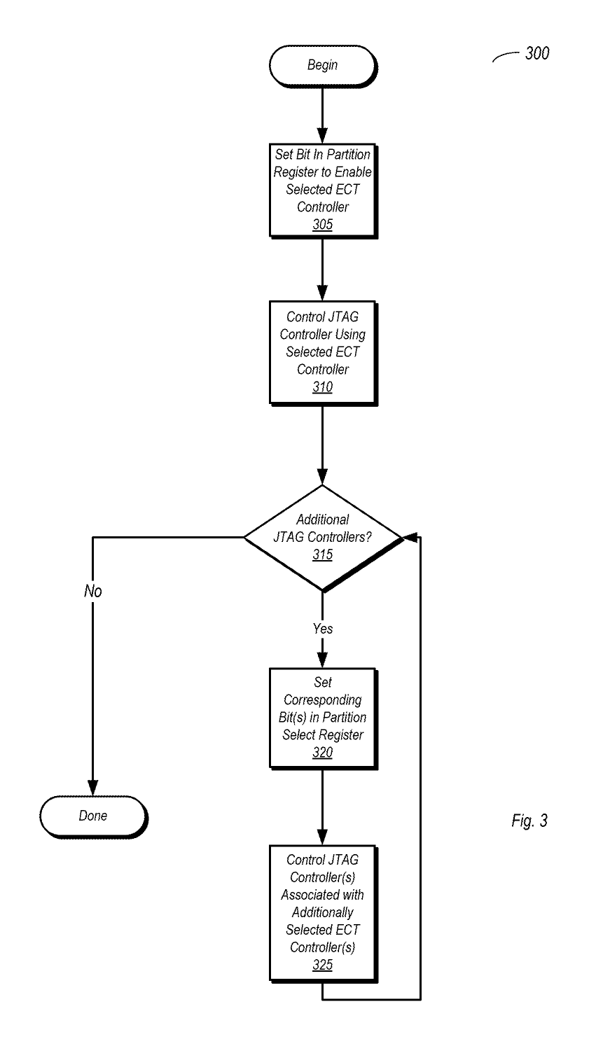

FIG. 3 is a flow diagram illustrating one embodiment of a method for controlling a JTAG controller using an ECT controller. Method 300 as illustrated herein may be performed with various embodiments of the hardware discussed above, as well as with other embodiments not explicitly described herein. Furthermore, while method 300 is discussed in terms of ECT controllers and JTAG controllers, embodiments of this method that apply to controllers having other protocols are possible and contemplated.

Method 300 begins with the setting of at least one bit in a partition selection register (PSR; block 305) in order to enable a selected ECT controller. The method may also set a bit in a JTAG register of a chip-level JTAG controller to enable an internal JTAG controller that corresponds to the selected ECT controller. The setting of the bit in the PSR may enable the selected ECT controller to control its associated JTAG controller (block 310). Controlling the JTAG controller may include the ECT controller inputting instructions and data into the former in order to conduct various tests and debugging routine, as well as to extract the data from such operations.

If an additional JTAG controller is to be used (block 315, yes), then another bit is set in the PSR (block 320) to enable a corresponding ECT controller. The ECT controller may then control the JTAG controller (block 325) in the manner described above. Moreover, the ECT controller may control the JTAG controller separately and independently over the other ECT controllers controlling their respectively coupled JTAG controllers. The method then returns to block 315, and may repeat blocks 320 and 325 as many times as necessary. If no other JTAG controllers are to be enable, (block 315, no), the method is complete.

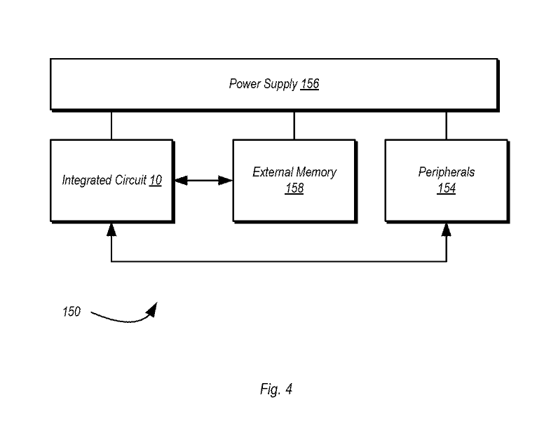

Turning next to FIG. 4, a block diagram of one embodiment of a system 150 is shown. In the illustrated embodiment, the system 150 includes at least one instance of the integrated circuit 10 coupled to external memory 158. The integrated circuit 10 is coupled to one or more peripherals 154 and the external memory 158. A power supply 156 is also provided which supplies the supply voltages to the integrated circuit 10 as well as one or more supply voltages to the memory 158 and/or the peripherals 154. In some embodiments, more than one instance of the integrated circuit 10 may be included (and more than one external memory 158 may be included as well).

The peripherals 154 may include any desired circuitry, depending on the type of system 150. For example, in one embodiment, the system 150 may be a mobile device (e.g. personal digital assistant (PDA), smart phone, etc.) and the peripherals 154 may include devices for various types of wireless communication, such as WiFi, Bluetooth, cellular, global positioning system, etc. The peripherals 154 may also include additional storage, including RAM storage, solid-state storage, or disk storage. The peripherals 154 may include user interface devices such as a display screen, including touch display screens or multitouch display screens, keyboard or other input devices, microphones, speakers, etc. In other embodiments, the system 150 may be any type of computing system (e.g. desktop personal computer, laptop, workstation, tablet, etc.).

The external memory 158 may include any type of memory. For example, the external memory 158 may be SRAM, dynamic RAM (DRAM) such as synchronous DRAM (SDRAM), double data rate (DDR, DDR2, DDR3, LPDDR1, LPDDR2, etc.) SDRAM, RAMBUS DRAM, etc. The external memory 158 may include one or more memory modules to which the memory devices are mounted, such as single inline memory modules (SIMMs), dual inline memory modules (DIMMs), etc.

Numerous variations and modifications will become apparent to those skilled in the art once the above disclosure is fully appreciated. It is intended that the following claims be interpreted to embrace all such variations and modifications.

What is claimed is:

1. An integrated circuit comprising:
a plurality of Joint Test Action Group (JTAG) controllers;
a plurality of Embedded Core Test (ECT) controllers coupled to corresponding ones of the JTAG controllers; and
a partition select register having a plurality of storage locations associated with corresponding ones of the ECT controllers, wherein each of the ECT controllers is configured to control its respectively coupled one of the plurality of JTAG controllers when a bit is set in its corresponding storage location.

2. The integrated circuit as recited in claim 1, wherein each of the ECT controllers is configured to control its respectively coupled JTAG controller in parallel with at least one other one of the ECT controllers controlling its respectively coupled JTAG controller.

3. The integrated circuit as recited in claim 1, wherein a first one of the ECT controllers is configured to control its respectively coupled JTAG controller independently of a second one of the ECT controllers controlling its respectively coupled JTAG controller.

4. The integrated circuit as recited in claim 1, further comprising a JTAG register having a plurality of storage locations associated with corresponding ones of the plurality of JTAG controllers, wherein each of the JTAG controllers is configured become active responsive to the setting of a bit in its corresponding of storage locations in the JTAG register.

5. The integrated circuit as recited in claim 4, wherein the integrated circuit includes a plurality of partitions, wherein the plurality of partitions includes a test partition, the test partition including the partition select register and the JTAG register.

6. The integrated circuit as recited in claim 5, wherein two or more of the partitions include at least one JTAG controller and at least one ECT controller.

7. The integrated circuit as recited in claim 1, wherein a given one of the ECT controllers is configured to control a test mode select (TMS) signal input to its respectively coupled JTAG controller.

8. The integrated circuit as recited in 1, where wherein a given one of the ECT controllers is configured to control inputting of data into the test data input (TDI) of its respectively coupled JTAG controller.

9. The integrated circuit as recited in claim 1, wherein each of the ECT controllers is configured to gate a test clock signal provided to it respectively coupled JTAG controller.

10. A method comprising:
controlling a first Joint Test Action Group (JTAG) controller using a first Embedded Core Test (ECT) controller;
controlling a second JTAG controller using a second ECT controller separately and independently of controlling the first JTAG controller using the first ECT controller.

11. The method as recited in claim 10, further comprising:
activating the first ECT controller to control the first JTAG controller by setting a first bit in a partition register; and
activating the second ECT controller to control the second JTAG controller by setting a second bit in the partition register.

12. The method as recited in claim 11, further comprising:
activating the first JTAG controller by setting a first bit in a JTAG register; and
activating the second JTAG controller by setting a second bit in the JTAG register.

13. The method as recited in claim 10, further comprising the first and second ECT controllers placing the first and second JTAG controllers, respectively, in a test mode by asserting a respective test mode select (TMS) signal.

14. The method as recited in claim 10, further comprising the first and second ECT controllers shifting data into the first and second JTAG controllers, respectively, through respective test data inputs of the first and second JTAG controllers.

15. The method as recited in claim 10, further comprising the first and second ECT controllers gating a test clock signal provided to the first and second JTAG controllers, respectively.

16. An apparatus comprising:
a first plurality of test controllers each configured to operate according to a first protocol;
a second plurality of test controllers each configured to operation according to a second protocol; and
a first register having a first plurality of storage locations, wherein each of the second plurality of test controllers is associated with one of the first plurality of storage locations, and wherein each of the second plurality of test controllers is configured to control its respectively coupled one of the first plurality of test controllers when a bit in its associated one of the first plurality of storage locations is set.

17. The apparatus as recited in claim 16, wherein a first one of the second plurality of test controllers is configured to control its respectively coupled one of the first plurality of test controllers in parallel with a second one of the second plurality of test controllers controlling its respectively coupled one of the first plurality of test controllers.

18. The apparatus as recited in claim 16, wherein each of the second plurality of test controllers is configured to control its respectively coupled one of the first plurality of test controllers independently of other ones of the second plurality of test controllers controlling their respectively coupled one of the first plurality of test controllers

19. The apparatus as recited in claim 16, further comprising a second register having a second plurality of storage locations, wherein each of the first plurality of test controllers is associated with a respective one of the second plurality of storage locations, and wherein each of the first plurality of test controllers is configured to become active responsive to a bit being set in its respective one of the second plurality of storage locations.

20. The apparatus as recited in claim 16, wherein each of the second plurality of test controllers is configured to place its respective one of the first plurality of test controllers in a test mode, and further configured to gate a clock signal provided to its respective one of the first plurality of test controllers.
